(19) United States
(12) Patent Application Publication
(10) Pub. No.: US 2010/0181585 A1
(43) Pub. Date: Jul. 22, 2010

(54) ILLUMINATION SYSTEM COMPRISING A COMPOUND WITH LOW THERMAL EXPANSION COEFFICIENT

(75) Inventors: Thomas Juestel, Eindhoven (NL); Cornelis Reinder Ronda, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., Eindhoven (NL)

(21) Appl. No.: 12/530,628

(22) PCT Filed: Mar. 10, 2008
(86) PCT No.: PCT/IB08/50858

§ 371 Date: Mar. 9, 2010

(30) Foreign Application Priority Data
Mar. 12, 2007 (EP) 07103962.2

(51) Int. Cl. H01L 33/00

(52) U.S. Cl. 257/98; 257/E33.061; 257/E33.067

(57) ABSTRACT

The invention relates to an illumination system with a material having a low or negative thermal expansion coefficient in order to compensate for the thermal expansion of the further materials present in the illumination system.

### FIELD OF THE INVENTION

The present invention is directed to novel materials for light emitting devices, especially to the field of novel materials for LEDs

### BACKGROUND OF THE INVENTION

Phosphor converted light emitting diodes (pcLEDs) are based on a blue or UV light emitting die, which is usually made out of (AlInGa)N and at least one luminescent layer, which is usually deposited onto the chip as a silicone suspension.

In order to emit white light, usually blue-emitting (In,Ga)N LEDs are converted into white light emitting LEDs either by a yellow-orange phosphor (e.g. YAG:Ce) or by a two component phosphor blend, containing a yellow- and a red-emitting one.

An alternative second approach is presently applied to achieve warm-white LEDs, whereby the employed phosphors are YAG:Ce in a blend with a red emitting material comprising Eu²⁺ in a covalent lattice, e.g. (Ca,Sr)S:Eu, CaAlSiN₃:Eu, or (Ba,Sr,Ca)₂Si₅N₈:Eu.

Especially the reliability of phosphor converted LEDs is an important issue in the industrialization of these illumination systems.

### SUMMARY OF THE INVENTION

It is an object of the present invention to provide an illumination system which is at least partly able to overcome the above-mentioned drawbacks and is especially usable within a wide range of applications and especially allows the fabrication and/or setup of highly reliable phosphor converted LEDs.

This object is solved by an illumination system according to claim 1 of the present invention. Accordingly, an illumination system, especially a LED is provided comprising a composite material with a thermal expansion coefficient α of ≧−2*10⁻⁶/K and ≦2*10⁻⁶/K.

Such a material has shown for a wide range of applications within the present invention to have at least one of the following advantages:
Using this composite material, the operational lifetime of the LED can be greatly increased for a wide range of applications within the invention due to the lesser (smaller) probability of cracking and/or stress within the composite material.
Due to the lesser (smaller) thermal expansion, the LED may be made more compact for a wide range of applications within the present invention
For a wide range of applications, also the contact between the luminescent materials in the LED may be increased.

It should be noted that an illumination system according to the present invention may have several build-ups which may be used simultaneously and/or alternatively and each represent preferred embodiments of the present invention:
The composite material may be placed on the blue-emitting die and further phosphor materials (such as, but not limited to yellow-orange phosphors, red-emitting phosphors and the like) may be embedded inside the composite material.
One or more materials within the composite material may also serve as luminescent materials so that at least some (or some part) of the phosphor materials may be omitted.
The composite material may be present in a matrix-, gel- and/or glass-like form surrounding and/or covering the blue-emitting die; however according to an alternative embodiment of the present invention, the composite material may also be present in form of a solid, e.g. a ceramic.

According to a preferred embodiment of the present invention, the illumination system comprises a composite material with a thermal expansion coefficient α of ≧−1*10⁻⁶/K and ≦1*10⁻⁶/K, more preferred ≦−0.5*10⁻⁶/K and ≦0.5*10⁻⁶/K

This has been shown to lead to a material with further improved features for a wide range of application within the present invention.

According to a preferred embodiment of the present invention, the composite material comprises at least one first material with a thermal expansion coefficient α of ≦0*10⁻⁶/K.

By doing so, it has been found in practice that the desired thermal expansion rate for the composite material may be set easily and efficiently for a wide range of applications within the present invention.

According to a preferred embodiment of the present invention, the first material is an oxidic material.

According to a preferred embodiment of the present invention, the first material has a band gap of ≧2.75 eV.

This has been shown to lead to a material with further improved features for a wide range of application within the present invention.

According to a preferred embodiment of the present invention, the first material has a Debye-Temperature of ≧500 K and ≦2000 K

This has been shown to lead to a material with further improved features for a wide range of application within the present invention.

Preferably the first material has a Debye-Temperature of ≧700 K and ≦1700 K, more preferred ≧1000 K and ≦1500 K.

According to a preferred embodiment of the present invention, the first material comprises a material selected out of the group comprising
M₂W₃₋ₓMoₓO₁₂, with M selected out of the group Sc, Y, La, Gd, Lu rare earth metals or mixtures thereof and x≧0 and ≦3
AMW₂₋ₓMoₓO₈, with A selected out of the group comprising Li, Na, K, Rb, Cs or mixtures thereof M selected out of the group Sc, Y, La, Gd, Lu rare earth metals or mixtures thereof and x≧0 and ≦2
XYMW₁₋ₓMoₓO₈, with X selected out of the group comprising Ca, Sr, Ba or mixtures thereof, Y selected out of the group comprising Nb, Ta or mixtures thereof and M selected out of the group Sc, Y, La, Gd, Lu rare earth metals or mixtures thereof and x≧0 and ≦1.
PbTiO₃,
ZrW₂O₈,
AlPO₄-17 (which is a zeolite e.g. described in Chem. Mater., 10 (7), 2013-2019, 1998, which is fully incorporated by reference)
or mixtures thereof.

These materials have proven themselves in practice for a wide range of applications within the present invention.

According to a preferred embodiment, the first material comprises a luminescent material, which is capable of absorbing at least partly in the UV or blue-emitting wavelength region and emit visible light in a wavelength region between ≧420 and ≦800 nm.

According to a preferred embodiment, the first material comprises a luminescent material selected out of the group:
M₂W₃₋ₓMoₓO₁₂:RE with M selected out of the group Sc, Y, La, Gd, Lu rare earth metals or mixtures thereof, x≧0 and ≦3 and RE selected out of the group comprising Eu, Pr, Sm, Dy or mixtures thereof
AMW₂₋ₓMoₓO₈:RE with A selected out of the group comprising Li, Na, K, Rb, Cs or mixtures thereof M selected out of the group Sc, Y, La, Gd, Lu rare earth metals or mixtures thereof, x≧0 and ≦2 and RE selected out of the group comprising Eu, Pr, Sm, Dy or mixtures thereof
XYMW₁₋ₓMoₓO₈:RE with X selected out of the group comprising Ca, Sr, Ba or mixtures thereof, Y selected out of the group comprising Nb, Ta or mixtures thereof and M selected out of the group Sc, Y, La, Gd, Lu rare earth metals or mixtures thereof x≧0 and ≦1 and RE selected out of the group comprising Eu, Pr, Sm, Dy or mixtures thereof.
or mixtures thereof.

According to a preferred embodiment of the present invention, the doping level is ≧0.001% and ≦100%, preferably ≦25%.

This has been shown to lead to a material with further improved lighting features for a wide range of application within the present invention. Preferably, the doping level is ≧0.1% and ≦10%, more preferred ≧1% and ≦5%.

Preferably the at least first material is provided as a powder.

If the at least first material is provided at least partially as a powder, it is especially preferred that the powder has a d₅₀ of ≧2.5 μm and ≦25, preferably ≦15 μm. This has been shown to be advantageous for a wide range of applications within the present invention.

According to a preferred embodiment of the present invention, the composite material comprises at least one second matrix material selected out of the group comprising silicone, glass, polymers, resins or mixtures thereof.

According to a preferred embodiment of the present invention, the ratio of the first material: the second material (in weight/weight) is ≧0.1:1 and ≦10:1, preferably ≧0.3:1 and ≦3:1.

According to a preferred embodiment of the present invention, the illumination system includes a blue-emitting die whereby the thermal expansion coefficient of the composite material is matched with the thermal expansion coefficient of the blue-emitting die.

The term “matched” especially includes that the blue-emitting die and the composite material have essentially the same thermal expansion coefficient and/or that the thermal expansion coefficient of the blue-emitting die and the composite material differ by ≦10%, preferably ≦5%. By doing so, the two components may be in very close contact for a wide range of applications within the present invention, leading to excellent cooling of the LED die, which in turn allows large operation currents.

On the other hand, the term “matched” especially includes that the composite material has a negative thermal expansion coefficient, however the thermal expansion coefficient of the blue-emitting die and the composite material have essentially the same absolute value or differ by ≦10%, preferably ≦5%. By doing so, the expansion of the die would be “compensated” by the composite material, which allows for a wide range of applications within the present invention to build a more compact illumination system.

The present invention furthermore relates to an illumination system, especially a LED, comprising at least one material with a thermal expansion coefficient α≦6*10⁻⁶/K.

Such a material has shown for a wide range of applications within the present invention to have at least one of the following advantages:
Using such a material, the operational lifetime of the LED can be greatly increased for a wide range of applications within the invention due to the lesser probability of cracking and/or stress within the composite material.
Due to the lesser thermal expansion, the LED may be made more compact for a wide range of applications within the present invention. According to a preferred embodiment of the present invention, the thermal expansion coefficient of said material is chosen as to at least partly counterbalance the thermal expansion of the blue-emitting die.
For a wide range of applications, also the optical contact between the luminescent materials in the LED may be increased.
For a wide range of applications it has been surprisingly found that due to the material the heat dissipation from the blue-emitting die may be greatly increased, which furthermore increases the lifetime of the LED.
In case the LED is mounted and/or provided on a board or board-like structure it is for a wide range of applications especially possible that the thermal expansion of the LED together with said first material is matched to the thermal expansion of the board, which is actually a preferred embodiment of the present invention.

According to a further embodiment of the present invention, the illumination system comprises at least one material with a thermal expansion coefficient α≦4*10⁻⁶/K, preferably α≦2*10⁻⁶/K and most preferred α≦0*10⁻⁶/K.

According to a preferred embodiment of the present invention, said material is an oxidic material.

According to a preferred embodiment of the present invention, said material has a band gap of ≧2.75 eV.

According to a preferred embodiment of the present invention, said material has a Debye-Temperature of ≧500 K and ≦2000 K.

This has been shown to lead to a material with further improved features for a wide range of application within the present invention.

Preferably the said material has a Debye-Temperature of ≧700 K and ≦1700 K, more preferred ≧1000 K and ≦1500 K.

According to a preferred embodiment of the present invention, said material comprises a material selected out of the group comprising
M₂W₃₋ₓMoₓO₁₂, with M selected out of the group Sc, Y, La, Gd, Lu rare earth metals or mixtures thereof and x≧0 and ≦3
AMW₂₋ₓMoₓO₈, with A selected out of the group comprising Li, Na, K, Rb, Cs or mixtures thereof M selected out of the group Sc, Y, La, Gd, Lu rare earth metals or mixtures thereof and x≧0 and ≦2
XYMW₁₋ₓMoₓO₈, with X selected out of the group comprising Ca, Sr, Ba or mixtures thereof, Y selected out of the group comprising Nb, Ta or mixtures thereof and M selected out of the group Sc, Y, La, Gd, Lu rare earth metals or mixtures thereof and x≧0 and ≦1.
PbTiO₃,
ZrW₂O₈,
AlPO₄-17 (which is a zeolite e.g. described in Chem. Mater., 10 (7), 2013-2019, 1998, which is fully incorporated by reference)
or mixtures thereof.

These materials have proven themselves in practice for a wide range of applications within the present invention.

According to a preferred embodiment, said material comprises a luminescent material, which is capable of absorbing at least partly in the UV or blue-emitting wavelength region and emit visible light in a wavelength region between ≧420 nm and ≦800 Y.

According to a preferred embodiment, said material comprises a luminescent material selected out of the group:
M₂W₃₋ₓMoₓO₁₂:RE with M selected out of the group Sc, La, Y, rare earth metals or mixtures thereof, x≧0 and ≦3 and RE selected out of the group comprising Eu, Pr, Sm, Dy or mixtures thereof
AMW₂₋ₓMoₓO₈:RE with A selected out of the group comprising Li, Na, K, Rb, Cs or mixtures thereof M selected out of the group Sc, La, Y, rare earth metals or mixtures thereof, x≧0 and ≦2 and RE selected out of the group comprising Eu, Pr, Sm, Dy or mixtures thereof
XYMW₁₋ₓMoₓO₈:RE with X selected out of the group comprising Ca, Sr, Ba or mixtures thereof, Y selected out of the group comprising Nb, Ta or mixtures thereof and M selected out of the group Sc, Y, La, Gd, Lu rare earth metals or mixtures thereof, x≧0 and ≦1 and RE selected out of the group comprising Eu, Pr, Sm, Dy or mixtures thereof
or mixtures thereof.

According to a preferred embodiment of the present invention, the doping level is ≧0.001% and ≦100%, preferably 25%.

This has been shown to lead to a material with further improved lighting features for a wide range of application within the present invention. Preferably, the doping level is ≧0.1% and ≦10%, more preferred ≧1% and ≦5%.

According to a preferred embodiment of the present invention, the illumination system includes a blue-emitting die whereby the thermal expansion coefficient of the material is matched with the thermal expansion coefficient of the blue-emitting die.

The term “matched” especially includes that the blue-emitting die and the material have essentially the same thermal expansion coefficient and/or that the thermal expansion coefficient of the blue-emitting die and the material differ by ≦10%, preferably ≦5%. By doing so, the two components may be in very close contact for a wide range of applications within the present invention, leading to excellent cooling of the LED die, which in turn allows large operation currents

On the other hand, the term “matched” especially includes that the composite material has a negative thermal expansion coefficient, however the thermal expansion coefficient of the blue-emitting die and the said material have essentially the same absolute value or differ by ≦10%, preferably ≦5%. By doing so, the expansion of the die would be “compensated” by the said material, which allows for a wide range of applications within the present invention to build a more compact illumination system.

Preferably the at least one material is provided as powder and/or as ceramic material.

If the at least one material is provided at least partially as a powder, it is especially preferred that the powder has a d₅₀ of ≧5 μm and ≦25 μm, preferably ≦15 μm. This has been shown to be advantageous for a wide range of applications within the present invention.

According to a preferred embodiment of the present invention, the at least one material is at least partly provided as at least one ceramic material.

The term “ceramic material” in the sense of the present invention means and/or includes especially a crystalline or polycrystalline compact material or composite material with a controlled amount of pores or which is pore free.

The term “polycrystalline material” in the sense of the present invention means and/or includes especially a material with a volume density larger than 90% of the main constituent, consisting of more than 80% of single crystal domains, with each domain being larger than 0.5 μm in diameter and having different crystallographic orientations. The single crystal domains may be connected by amorphous or glassy material or by additional crystalline constituents.

According to a preferred embodiment, the at least one material has a density of ≧90% and ≦100% of the theoretical density. This has been shown to be advantageous for a wide range of applications within the present invention since then the luminescent properties of the at least one ceramic material may be increased.

More preferably the at least one ceramic material has a density of ≧97% and ≦100% of the theoretical density, yet more preferred ≧98% and ≦100%, even more preferred ≧98.5% and ≦100% and most preferred ≧99.0% and ≦100%.

According to a preferred embodiment of the present invention, the surface roughness RMS (disruption of the planarity of a surface; measured as the geometric mean of the difference between highest and deepest surface features) of the surface(s) of the at least one ceramic material is 0.001 μm and 1 μm.

According to an embodiment of the present invention, the surface roughness of the surface(s) of the at least one ceramic material is ≧0.005 μm and ≦0.8 μm, according to an embodiment of the present invention ≧0.01 μm and ≦0.5 μm, according to an embodiment of the present invention ≧0.02 μm and ≦0.2 μm. and according to an embodiment of the present invention ≧0.03 μm and ≦0.15 μm.

According to a preferred embodiment of the present invention, the specific surface area of the at least one ceramic material is ≧10⁻⁷ m²/g and ≦0.1 m²/g.

An illumination system according to the present invention may be of use in a broad variety of systems and/or applications, amongst them one or more of the following:
Office lighting systems
Household application systems
Shop lighting systems,
Home lighting systems,
Accent lighting systems,
Spot lighting systems,
Theatre lighting systems,
Fibre-optics application systems,
Projection systems,
Self-lit display systems,
Pixelated display systems,
Segmented display systems,
Warning sign systems,
Medical lighting application systems,
Indicator sign systems, and
Decorative lighting systems
Portable systems
Automotive applications
Green house lighting systems
Application in sensors

The aforementioned components, as well as the claimed components and the components to be used in accordance with the invention in the described embodiments, are not subject to any special exceptions with respect to their size, shape, material selection and technical concept such that the selection criteria known in the pertinent field can be applied without limitations.

### BRIEF DESCRIPTION OF THE DRAWINGS

Additional details, features, characteristics and advantages of the object of the invention are disclosed in the subclaims, the figures and the following description of the respective figures and examples, which—in an exemplary fashion—show several embodiments and examples of a at least one ceramic material for use in a light emitting device according to the invention as well as several embodiments and examples of an illumination system according to the invention.

FIG. 1 shows a schematic partial side view of a structure of a LED according to a first embodiment of the present invention;

FIG. 2 shows a schematic partial side view of a structure of a LED according to a first embodiment of the present invention;

FIG. 3 shows a schematic partial side view of a structure of a LED according to a third embodiment of the present invention

FIG. 4 shows an emission spectrum of an LED according to Example I of the present invention.

### DETAILED DESCRIPTION OF EMBODIMENTS

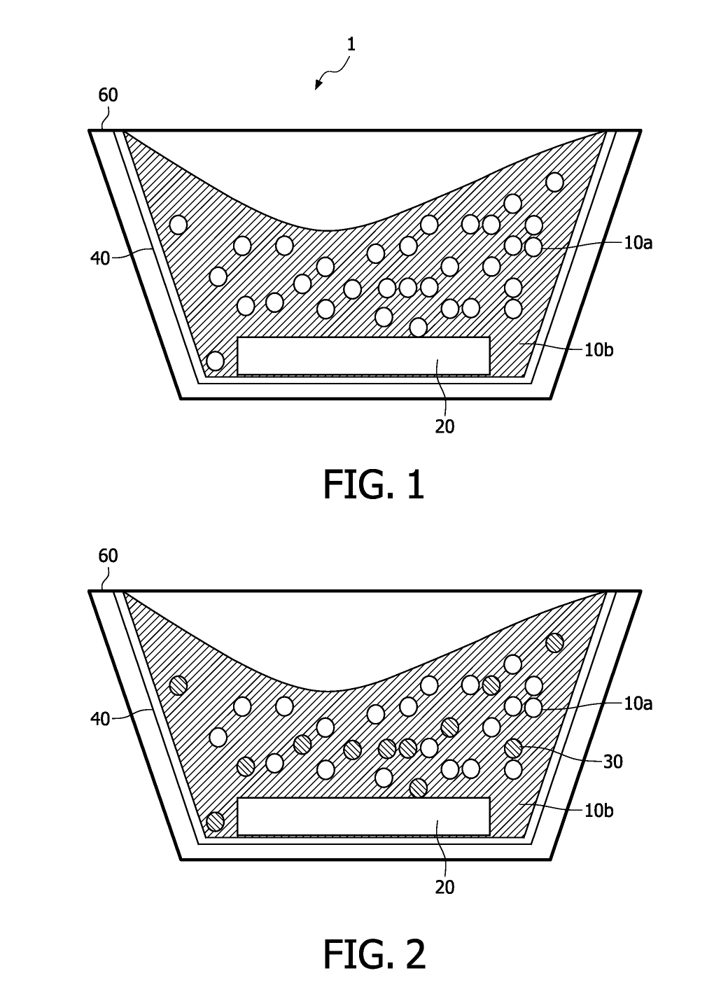

FIG. 1 shows a schematic partial side view of a structure of a LED according to a first embodiment of the present invention;

In this embodiment, a LED 1 comprises a LED body 60, in which a mirror 40 is inserted. A blue-emitting die 20 (e.g. consisting out of InGaN or any other suitable material) is deposited within the mirror 40 and surrounded by a composite material, which comprises a first material 10a which has a low or negative thermal expansion coefficient (as described above) embedded in a second material 10b, which may be made out of silicone, PMMA etc.

The first material 10a is furthermore luminescent and therefore serves to convert part of the light emitted by the die 20 in order to achieve a warm-white LED. The first material 10a may to this end not be uniform but comprise itself several materials (as described above).

FIG. 2 shows a schematic partial side view of a structure of a LED according to a second embodiment of the present invention. This embodiment differs from that of FIG. 1 that the first material 10a is not luminescent, but rather a converting phosphor 30 is furthermore present. This phosphor material 30 may be chosen from any material known in the field. It is apparent that this phosphor material 30 does not need to be uniform, also several materials may be present in the matrix 10b.

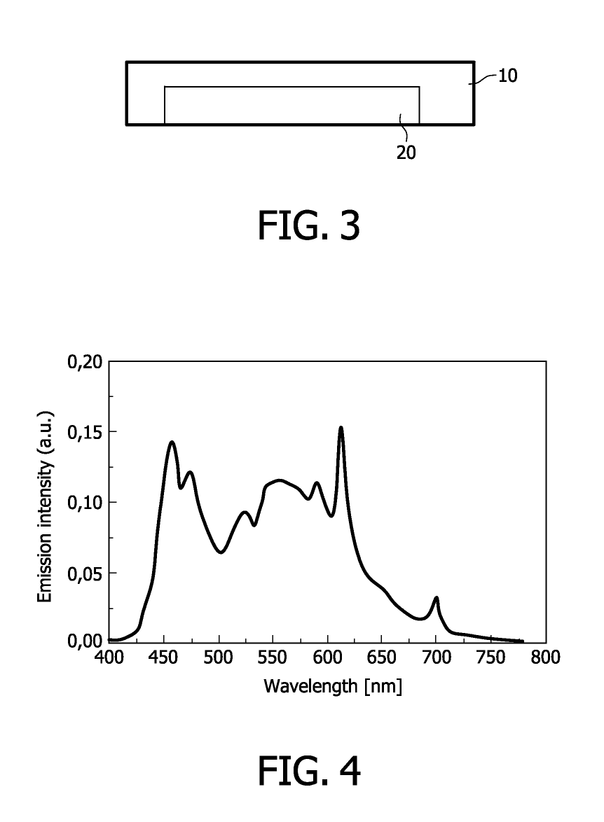

FIG. 3 shows a schematic partial side view of a structure of a LED according to a third embodiment of the present invention. In this embodiment, the die 20 is surrounded by a material 10 with a low thermal expansion coefficient, as described above. As the LED and the ceramic material have the same thermal expansion, the two components can be in very close contact, leading to excellent cooling of the LED die, which in turn allows large operation currents.

The present invention will furthermore be understood by the following Example I:

### EXAMPLE I

In this example, a LED was made comprising a die, that is surrounded by a ceramic composite material with a thermal expansion coefficient close to zero. The composite is composed out of a Cerium doped garnet, i.e. (Y,Gd,Lu)₃Al₅0₁₂:Ce,Pr and out of a Europium doped tungstate or molybdate, i.e. LiLaW₂O₈:Eu. The spectrum of the LED is shown in FIG. 4.

The particular combinations of elements and features in the above detailed embodiments are exemplary only; the interchanging and substitution of these teachings with other teachings in this and the patents/applications incorporated by reference are also expressly contemplated. As those skilled in the art will recognize, variations, modifications, and other implementations of what is described herein can occur to those of ordinary skill in the art without departing from the spirit and the scope of the invention as claimed. Accordingly, the foregoing description is by way of example only and is not intended as limiting. The invention's scope is defined in the following claims and the equivalents thereto. Furthermore, reference signs used in the description and claims do not limit the scope of the invention as claimed.

1. Illumination system, especially a LED comprising a composite material with a thermal expansion coefficient α of ≧−2*10⁻⁶ /K and ≦2*10⁻⁶ /K

2. Illumination system according to claim 1, whereby the composite material comprises at least one first material with a thermal expansion coefficient α of ≦0*10⁻⁶ /K.

3. Illumination system according to claim 1, whereby the composite material comprises at least one second matrix material selected out of the group comprising silicone, glass, polymers, resins or mixtures thereof.

4. Illumination system according to claim 1, whereby the ratio of the first material: the second material (in weight/weight) is ≧0.1:1 and ≦10:1.

5. Illumination system, especially a LED, comprising at least one material with a thermal expansion coefficient α≦6*10⁻⁶ /K

6. Illumination system according to claim 5, whereby said material is an oxidic material.

7. Illumination system according to claim 5, whereby said material has a band gap of ≧2.75 eV.

8. Illumination system according to claim 5, whereby said material has a Debye-Temperature of ≧500 K and ≦2000 K.

9. Illumination system according to claim 5, whereby said material comprises a material selected out of the group comprising
M₂W₃₋ₓMoₓO₁₂, with M selected out of the group Sc, Y, La, Gd, Lu rare earth metals or mixtures thereof and x≧0 and ≦3
AMW₂₋ₓMoₓO₈, with A selected out of the group comprising Li, Na, K, Rb, Cs or mixtures thereof M selected out of the group Sc, Y, La, Gd, Lu rare earth metals or mixtures thereof and x≧0 and ≦2
XYMW₁₋ₓMoₓO₈, with X selected out of the group comprising Ca, Sr, Ba or mixtures thereof, Y selected out of the group comprising Nb, Ta or mixtures thereof and M selected out of the group Sc, Y, La, Gd, Lu rare earth metals or mixtures thereof and x≧0 and ≦1.
PbTiO₃,
ZrW₂O₈,
AlPO₄-17
or mixtures thereof.

10. A system comprising an illumination system according to claim 1, the system being used in one or more of the following applications:
Office lighting systems
Household application systems
Shop lighting systems,
Home lighting systems,
Accent lighting systems,
Spot lighting systems,
Theatre lighting systems,
Fibre-optics application systems,
Projection systems,
Self-lit display systems,
Pixelated display systems,
Segmented display systems,
Warning sign systems,
Medical lighting application systems,
Indicator sign systems, and
Decorative lighting systems
Portable systems
Automotive applications
Green house lighting systems
Application in sensors
